(19) United States
(12) Patent Application Publication
(10) Pub. No.: US 2012/0307425 A1
(43) Pub. Date: Dec. 6, 2012

(54) PORTABLE ELECTRONIC DEVICE AND BATTERY LOCKING MODULE

(75) Inventor: Huan-Chun Lo, Miaoli County (TW)

(73) Assignee: ALTEK CORPORATION, Hsinchu City (TW)

(21) Appl. No.: 13/227,480

(22) Filed: Sep. 8, 2011

(30) Foreign Application Priority Data
May 31, 2011 (TW) 100119042

(51) Int. Cl. H05K 7/00

(52) U.S. Cl. 361/679.01

(57) ABSTRACT

A portable electronic device and a battery locking module capable to lock the battery and the battery slot cover in the housing of the portable electronic device through a locking element and an elastic element are provided. Especially, through the improvement design of the arrangement of the battery locking module in the housing, not only the inner space of the portable electronic device can be saved, a fool proof function is also provided since the battery slot cover is disabled to cover the opening of the battery slot if the battery is in a wrong position.

### CROSS-REFERENCE TO RELATED APPLICATION

This application claims the priority benefit Taiwan application serial no. 100119042, filed on May 31, 2011. The entirety of the above-mentioned patent application is hereby incorporated by reference herein and made a part of this specification.

### BACKGROUND OF THE INVENTION

1. Field of the Invention

The present invention relates to a portable electronic device and the design of a battery locking module thereof, and more particularly to a modified design of a battery locking module.

2. Description of Related Art

Owing to advanced of semiconductor elements and display technologies, electronic devices have been continuously developed toward the trend of miniaturization, multiple functions, and portability. The most common portable electronic device includes a camera, a camcorder, a personal digital assistant (PDA), a mobile phone, a notebook computer, and so forth. To comply with the requirement for compactness, the portable electronic device often has a foldable design to reduce its dimensions. In general, the portable electronic device has a battery to provide power for system operation so that users are convenient to carry and use the portable electronic device. The battery is often disposed beneath the body of the portable electronic device or within the corner of the body. And the battery is fixed to the body by using limiting components.

In conventional portable electronic device, the battery is bounded from the fixing mechanism as soon as the cover is open, so that the users can easily take the battery out. However, if the cover is open under an incautious or unexpected condition, the function that the battery can freely bound from the fixing mechanism may lead to inconvenience for the users. In addition, in the conventional battery fixing mechanism the battery inserting direction is often designed to be perpendicular to the motion direction of the battery fixing mechanism. However, such configuration in portable electronic devices gradually fails to comply with the requirements in the market since the trends of lightness, thinness and compactness must be taken into account in designing the products.

### SUMMARY OF THE INVENTION

The present invention provides a portable electronic device in which the battery locking module of the portable electronic device has few parts, can effectively save the inner space of the portable electronic device and has a fool proof function being disabled to cover the battery slot cover when the battery is in a wrong orientation.

The present invention further provides a battery locking module adapted to use in a portable electronic device in which the battery locking module has few parts, can effectively save the inner space of the portable electronic device and has a fool proof function being disabled to cover the battery slot cover when the battery is in a wrong orientation.

The invention provides a portable electronic device including a housing, a battery and a battery locking module. The housing has a battery slot and a battery slot cover. The battery slot has an opening, and the battery slot cover covers the opening. The battery is inserted along a first direction and accommodated to the battery slot. The battery locking module includes a locking element and an elastic element. The locking element is disposed at a side of the battery slot and has a pivot, a pivoting end and a fixing end. The pivot is perpendicular to the first direction and parallel to the side of the battery slot. The pivoting end is disposed at the side through the pivot so that the fixing end is adapted to rotate along the pivot. The elastic element is disposed at the pivoting end. Herein when the locking element resists an elasticity of the elastic element and rotates along a direction being far away from the battery slot, the fixing end leaves the battery and the battery slot cover. When the locking element rotates along the pivot toward the battery slot, the fixing end fixes the battery and the battery slot cover.

In one embodiment of the present invention, the fixing end has a first fixing portion and a second fixing portion. The battery slot cover is fixed by the first fixing portion, and the battery is fixed by the second fixing portion.

In one embodiment of the present invention, the portable electronic device further includes a spring leaf disposed beneath the battery slot. The spring leaf is adapted to push the battery to the opening of the battery slot.

In one embodiment of the present invention, the pivoting end and the fixing end of the locking element are integrally formed.

In one embodiment of the present invention, the elastic element is a torsion spring and disposed around the pivot.

In one embodiment of the present invention, the portable electronic device can be a camera, a portable phone or a tablet personal computer.

The invention provides a battery locking module adapted to use in a portable electronic device. The portable electronic device includes a housing and a battery. The housing has a battery slot and a battery slot cover. The battery is inserted along a first direction and accommodated to the battery slot. The battery slot cover covers the battery slot. The battery locking module includes a locking element and an elastic element. The locking element is disposed at a side of the battery slot and has a pivot, a pivoting end and a fixing end. The pivot is perpendicular to the first direction and parallel to the side of the battery slot. The pivoting end is disposed at the side through the pivot so that the fixing end is adapted to rotate along the pivot. The elastic element is disposed at the pivoting end. Herein when the locking element resists an elasticity of the elastic element and rotates along a direction being far away from the battery slot, the fixing end leaves the battery and the battery slot cover. When the locking element rotates along the pivot toward the battery slot, the fixing end fixes the battery and the battery slot cover.

In one embodiment of the present invention, the fixing end has a first fixing portion and a second fixing portion. The battery slot cover is fixed by the first fixing portion and the battery slot is fixed by the second fixing portion.

In an embodiment of the present invention, the pivoting end and the fixing end of the locking element are integrally formed.

In one embodiment of the present invention, the elastic element is a torsion spring and disposed around the pivot.

In view of the above, in the portable electronic device and the battery locking module, the battery and the battery slot cover is fixed to the housing of the portable electronic device through the improved design of the locking element and the elastic element. The portable electronic device has the advantages of effectively saving the inner space of the portable electronic device and having a fool proof function being disabled to cover the battery slot cover when the battery is in a wrong orientation.

In order to make the aforementioned and other features and advantages of the invention more comprehensible, embodiments accompanying figures are described in detail below.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic view of a portable electronic device according to one embodiment of the present invention.

FIG. 2 is a schematic view of the battery locking module of the portable electronic device in FIG. 1.

FIG. 3 illustrates the schematic view when the battery of the portable electronic device in FIG. 1 is inserted into the battery slot.

### DESCRIPTION OF EMBODIMENTS

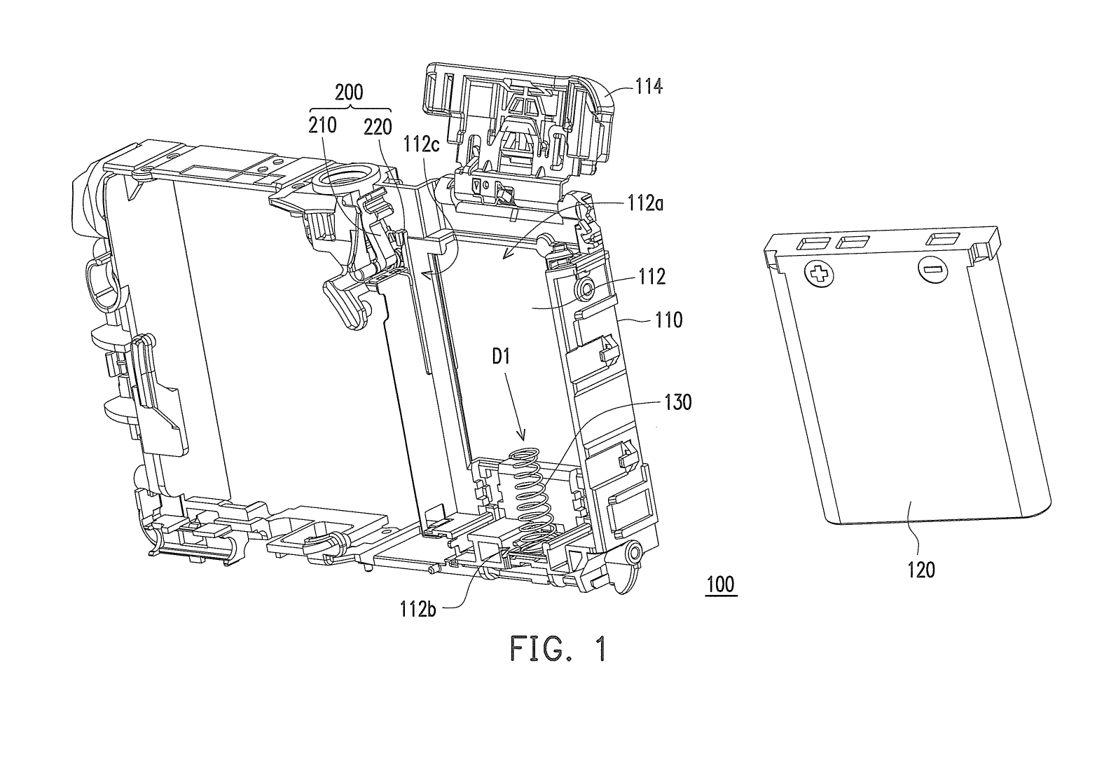

FIG. 1 is a schematic view of a portable electronic device according to one embodiment of the present invention. Referring to FIG. 1, the portable electronic device 100 is a camera, a mobile phone or a tablet personal computer, for example. In the present embodiment, it is taken as an example that the portable electronic device 100 is a camera. The portable electronic device 100 has a housing 110, a battery 120 and a spring leaf 130. The housing 110 has a battery slot 112 and a battery slot cover 114. The battery slot 112 has an opening 112a. The battery slot cover 114 is disposed at the side of the opening 112a and covers the opening 112a. The spring leaf 130 is disposed at the bottom 112b of the battery slot 112. The spring leaf 130 is adapted to push the battery 120 to the opening 112a. The spring leaf 130 can be a coil spring or a spring in sheet structure, and a coil spring is used in this embodiment.

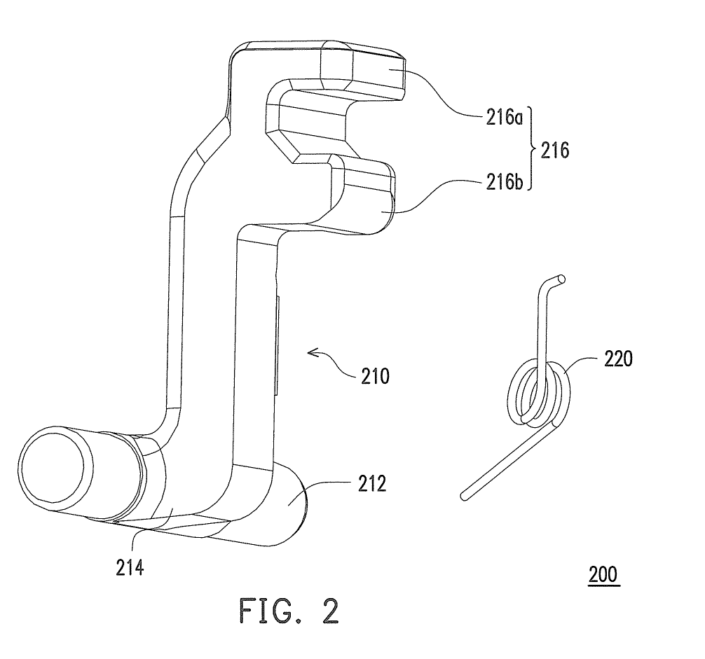

In the embodiment, a battery locking module 200 is disposed in the housing 110 of the portable electronic device 100 to fix the battery 120 within the battery slot 112. FIG. 2 is a schematic view of the battery locking module of the portable electronic device in FIG. 1. Please refer to FIG. 1 and FIG. 2. The battery locking module 200 includes a locking element 210 and an elastic element 220. The locking element 210 is disposed at a side 112c of the battery slot 112 and has a pivot 212, a pivoting end 214 and a fixing end 216. A first direction D1 is defined hereinafter as the inserting direction of the battery 120 into the battery slot 112. That is, the battery 120 is inserted along the first direction D1 and accommodated in the battery slot 112. The pivoting end 124 is disposed at the side 112c through the pivot 212. The pivot 212 is disposed perpendicular to the first direction D1 and parallel to the side 112c so that so that the fixing end 216 is adapted to rotate along the pivot 212.

As shown in FIG. 1, the battery locking module 200 is in a vertical rotatable configuration relative to the battery slot 112. Since the space at the side 112c of the battery slot 112 is used to dispose the locking element 210, the inner space of the battery slot 112 is substantially equal to the volume of the battery 120. It is so much different comparing to the conventional battery locking mechanism, since the inner space of the battery slot is unnecessary to be bigger than the volume of the battery in present embodiment. Thus, such configuration can save the inner space of the housing 110 of the portable electronic device 100.

Then, how the battery 120 and the battery slot cover 114 are fixed to the housing 110 is described as follows. The elastic element 220 of the battery locking module 200 is disposed at the pivoting end 214. The elastic element 220 can be a coil spring, a spring in a sheet structure or a torsion spring. As shown in FIG. 1 and FIG. 2, a torsion spring is used to dispose around the pivot 212. When the locking element 210 resists an elasticity of the elastic element 220 and rotates along a direction being far away from the battery slot 112, the fixing end 216 leaves the battery 120 and the battery slot cover 140. When the locking element 210 rotates along the pivot 212 toward the battery slot 112, the battery 120 and the battery slot cover 114 is fixed by the fixing end 216. The fixing end has a first fixing portion and a second fixing portion. And the fixing end 216 always tends toward the battery slot 112 because of the elastic element 220.

As shown in FIG. 2, the fixing end 216 has a first fixing portion 216a and a second fixing portion 216b. The battery slot cover 114 is fixed by the first fixing portion 216a, and the battery 120 is fixed by the second fixing portion 216b. The structure of the first fixing portion 216a and the second fixing portion 216b of the present embodiment is described in the following. The first fixing portion 216a and the second fixing portion 216b are formed by the structures extending from the fixing end 216 having limiting functions. And the ends of the first fixing portion 216a and the second fixing portion 216b to contact with the battery 120 and the battery slot cover 114 are designed to be smooth so as to prevent scratching. In addition, in the embodiment, the pivoting end 214 and the fixing end 216 of the locking element 210 can be integrally formed, for example. A recess which exactly accommodates the thickness of the battery slot cover 114 exists between the first fixing portion 216a and the second fixing portion 216b so that a portion of the battery slot cover 114 is placed into the recess to be fixed to the housing 110.

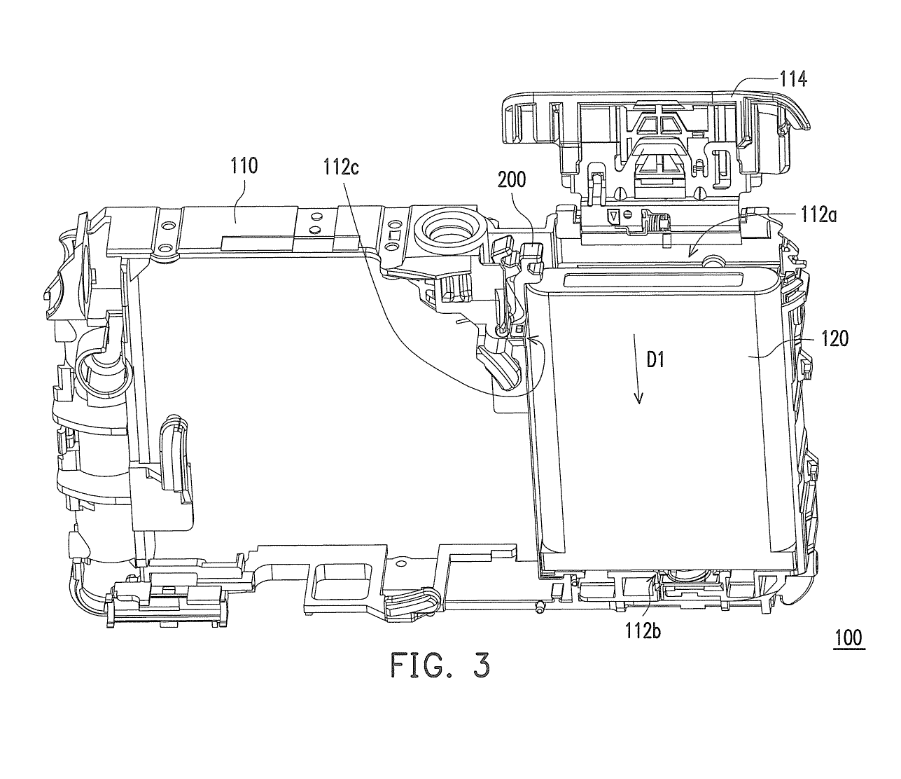

FIG. 3 illustrates the schematic view in which the battery of the portable electronic device in FIG. 1 is inserted into the battery slot. Please refer to FIG. 3, before inserting the battery 120 into the battery slot 112, the fixing portion 216 has to be pushed toward the side 112c of the battery slot 112 so that the battery 120 can be inserted into the battery slot 112 along the first direction D1, since the locking element 210 prevents the opening 112a because of the elastic element 220. At the same time, the battery 120 has to be pushed down and resist the elasticity of the spring leaf 130 to be totally accommodated in the battery slot 112. At this time, the battery 120 can be fixed by the second fixing portion 216b if the fixing portion 216 is bounded back to its original position. The battery slot cover 114 covers the opening and a portion of the battery slot cover 114 slides a small distance and is fixed by the first fixing portion 216a. If the battery 120 is to be taken out, the battery slot cover 114 has to be released and open from the first fixing portion 216a first, and then the fixing end 216 has to be pushed aside away from the battery slot 112 while resisting the elasticity of the elastic element 220 so that the second fixing portion 216b releases the battery 120. At this time, the battery 120 is bounded to the opening 112a because of the spring leaf 130 disposed at the bottom 112b of the battery slot 112, so that the user can easily to take the battery 120 out.

It has to be noted that, in the embodiment, once the battery 120 is in a wrong orientation, the battery 120 cannot be fixed within the battery slot 112 by the locking element 210, and it leads to the battery slot cover 114 being disabled to cover the opening 112a. Thus, such configuration with a fool proof function can alert the user. Furthermore, since the battery 120 is fixed in the battery slot 112 through the second fixing portion 216b, if the battery slot cover 114 is open under an incautious condition, the battery 120 is still fixed in the battery slot 112. Therefore, the unexpected event that once the battery slot cover 114 is open the battery 120 will be bounded to the opening 112a may not happen.

In view of the foregoing, the battery locking module of the invention has the advantages of having few parts and simple structure. Through the simple configuration of the locking element and the elastic element of the battery locking module, the portable electronic device not only can effectively save the inner space, but also has a fool proof function being disabled to cover the battery slot cover when the battery is in a wrong orientation.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A battery locking module, adapted to a portable electronic device, the portable electronic device comprising a housing and a battery, the housing having a battery slot and a battery slot cover, the battery slot having an opening, the battery slot cover covering the opening, the battery being inserted along a first direction and accommodated to the battery slot, the battery locking module comprising:
a locking element disposed at a side of the battery slot and the locking element having a pivot, a pivoting end and a fixing end, the pivot being perpendicular to the first direction and parallel to the side, the pivoting end is disposed at the side through the pivot so that the fixing end is adapted to rotate along the pivot; and
an elastic element disposed at the pivoting end;
wherein when the locking element resists an elasticity of the elastic element and rotates along a direction being far away from the battery slot, the fixing end leaves the battery and the battery slot cover, when the locking element rotates along the pivot toward the battery slot, the fixing end fixes the battery and the battery slot cover.

2. The battery locking module as claimed in claim 1, wherein the fixing end has a first fixing portion and a second fixing portion, the first fixing portion fixes the battery slot cover, and the second fixing portion fixes the battery.

3. The battery locking module as claimed in claim 1, wherein the pivoting end and the fixing end of the locking element are integrally formed.

4. The battery locking module as claimed in claim 1, wherein the elastic element is a torsion spring and disposed around the pivot.

5. A portable electronic device, comprising:
a housing having a battery slot and a battery slot cover, the battery slot having an opening, and the battery slot cover covering the opening;
a battery being inserted along a first direction and accommodated to the battery slot; and
a battery locking module comprising:
a locking element disposed at a side of the battery slot and the locking element having a pivot, a pivoting end and a fixing end, the pivot being perpendicular to the first direction and parallel to the side, the pivoting end is disposed at the side through the pivot so that the fixing end is adapted to rotate along the pivot; and
an elastic element disposed at the pivoting end;
wherein when the locking element resists an elasticity of the elastic element and rotates along a direction being far away from the battery slot, the fixing end leaves the battery and the battery slot cover, when the locking element rotates along the pivot toward the battery slot, the fixing end fixes the battery and the battery slot cover.

6. The portable electronic device as claimed in claim 5, wherein the fixing end has a first fixing portion and a second fixing portion, the first fixing portion fixes the battery slot cover, and the second fixing portion fixes the battery.

7. The portable electronic device as claimed in claim 5, further comprising a spring leaf disposed at the bottom of the battery slot, and the spring leaf adapted to push the battery toward the opening of the battery slot.

8. The portable electronic device as claimed in claim 5, wherein the pivoting end and the fixing end of the locking element are integrally formed.

9. The portable electronic device as claimed in claim 5, wherein the elastic element is a torsion spring and disposed around the pivot.

10. The portable electronic device as claimed in claim 5, wherein the portable electronic device is a camera, a portable phone or a tablet personal computer.
